(19) United States
(12) Patent Application Publication
(10) Pub. No.: US 2018/0235089 A1
(43) Pub. Date: Aug. 16, 2018

(54) WIRING BOARD AND MANUFACTURING METHOD OF WIRING BOARD

(71) Applicant: OLYMPUS CORPORATION, Tokyo (JP)

(72) Inventor: Kazuaki KOJIMA, Suwa-shi (JP)

(73) Assignee: OLYMPUS CORPORATION, Tokyo (JP)

(21) Appl. No.: 15/804,207

(22) Filed: Nov. 6, 2017

(30) Foreign Application Priority Data
Feb. 15, 2017 (JP) 2017-025691

(51) Int. Cl. H05K 3/20; H05K 1/11; H01L 21/768; H05K 1/18; H05K 3/10; H01L 21/48; H05K 3/40

(52) U.S. Cl. CPC H05K 3/205; H05K 1/115; H01L 21/76898; H05K 1/181; H05K 2201/09036; H01L 21/486; H05K 3/4038; H05K 3/4061; H05K 2203/0726; H05K 3/10

(57) ABSTRACT

For a wiring board, silicon including a first main surface and a second main surface is a base, a first conductor on the first main surface and a second conductor on the second main surface are connected by a through electrode formed of an electroplating layer disposed on an inner surface of a through hole, a bottom surface of which is the second conductor, and a hilling which is a continuous projecting portion is provided on the inner surface of the through hole from the first main surface to the second main surface in parallel with a depth direction.

### CROSS REFERENCE TO RELATED APPLICATION

This application claims the benefit of Japanese Application No. 2017-025691 filed in Japan on Feb. 15, 2017, the contents of which are incorporated herein by this reference.

### BACKGROUND OF THE INVENTION

### 1. Field of the Invention

The present invention relates to a wiring board in which a through electrode is disposed on an inner surface of a through hole, and a manufacturing method of the wiring board.

### 2. Description of the Related Art

In order to miniaturize an electronic device and improve performances, a technology of disposing an electroplating layer on an inner surface of a through hole of a wiring board and using the electroplating layer as a through electrode is used. However, a conduction failure sometimes occurs in the through electrode.

FIG. 1A and FIG. 1B illustrate a conventional wiring board 101 in which a defective through electrode 150 is disposed in a through hole H110 of a substrate 10.

Note that, in following description, drawings are schematic, it should be noted that a relation between a thickness and a width of individual parts and a ratio of the thicknesses of the respective parts or the like are different from actual ones, and even between the drawings, a part where the relation of mutual dimensions or the ratio is different is sometimes included. In addition, illustrations of some components and assignment of signs are sometimes omitted.

On an inner surface of the through hole H110, a bottom surface of which is a second conductor 20 on a second main surface 10SB of the wiring board 101, a conductive layer 30 is disposed. The through electrode 150 is an electroplating layer 160 simultaneously formed with a first conductor 140 on a first main surface 10SA with the conductive layer 30 as a cathode. However, the through electrode 150 is broken in a middle in a ring shape, and does not conduct the first conductor 140 and the second conductor 20.

It is because, as illustrated in FIG. 3, a resist residue 71 exists in the ring shape on the inner surface of the through hole H110 when the electroplating layer 160 is formed. The resist residue 71 is not conductive. Therefore, a non-plated area is generated in the ring shape, and the through electrode 150 is broken.

That is, as illustrated in FIG. 2, a positive photoresist 70 turns soluble to a developer when exposed to ultraviolet light (UV) through a mask 80. However, the photoresist 70 hangs down right under an opening of the through hole H110 to which the photoresist 70 is applied, and an overhung area 71B in the ring shape is generated in parallel with an opening surface (first main surface 10SA). When irradiation with ultraviolet light is obstructed by the overhung area 71B or an irradiation amount of the ultraviolet light to the thick overhung area 71B is insufficient, the resist residue 71 in the ring shape is generated.

Japanese Patent Application Laid-Open Publication No. 2012-231096 proposes a complicated development step for removing a photoresist inside a through hole.

Note that Japanese Patent Application Laid-Open Publication No. 2012-142414 describes that, as an opening shape of the through hole, a circle is preferable but the opening shape may be a polygon such as a square or a hexagon. In addition, Japanese Patent Application Laid-Open Publication No. 2010-16255 describes that the opening shape of the through hole may be any shape such as a circle, an ellipse, a triangle or a rectangle.

That is, conventionally, it is thought that the opening shape of the through hole may be any shape.

### SUMMARY OF THE INVENTION

A wiring board of an embodiment of the present invention is a wiring board with silicon as a base, including a first main surface and a second main surface opposing the first main surface, in which a first conductor on the first main surface and a second conductor on the second main surface are connected by a through electrode formed of an electroplating layer extending from the first conductor and disposed on an inner surface of a through hole, a bottom surface of which is the second conductor, and, on the inner surface of the through hole, at least either one of a groove which is a continuous recessed portion and a hilling which is a continuous projecting portion, is provided from the first main surface to the second main surface in parallel with a depth direction.

A manufacturing method of a wiring board of another embodiment is a manufacturing method of a wiring board with silicon as a base, including a first main surface and a second main surface, in which a first conductor on the first main surface and a second conductor on the second main surface are connected by a through electrode disposed on an inner surface of a through hole, a bottom surface of which is the second conductor, and includes: a process of forming the through hole from the first main surface to the second conductor of the second main surface; a process of disposing a conductive layer covering the first main surface and an inner surface and a bottom surface of the through hole; a process of coating a positive photoresist on the first main surface and the inner surface and the bottom surface of the through hole; a process of detaching the photoresist covering an area to dispose the first conductor of the first main surface and the inner surface and the bottom surface of the through hole by pattern exposure of ultraviolet light through a photomask and development; a process of disposing an electroplating layer with the conductive layer as an electrode; and a process of detaching the photoresist, and further removing the conductive layer not covered with the electroplating layer, and, on the inner surface of the through hole formed in the process of forming the through hole, at least either one of a groove and a hilling is provided from the first main surface to the second main surface in parallel with a depth direction.

### BRIEF DESCRIPTION OF THE DRAWINGS

FIG. 1A is a sectional view of a conventional wiring board;

FIG. 1B is a top view along an IB-IB line in FIG. 1A of the conventional wiring board;

FIG. 2 is a sectional view for describing a manufacturing method of the conventional wiring board;

FIG. 3 is a sectional view for describing the manufacturing method of the conventional wiring board;

FIG. 4 is a perspective view of a wiring board of an embodiment;

FIG. 5A is a top view of the wiring board of the embodiment;

FIG. 5B is a top view along a VB-VB line in FIG. 5A of the wiring board of the embodiment;

FIG. 6 is a flowchart for describing a manufacturing method of the wiring board of the embodiment;

FIG. 7A is a top view for describing the manufacturing method of the wiring board of the embodiment;

FIG. 7B is a sectional view along a VIIB-VIIB line in FIG. 7A for describing the manufacturing method of the wiring board of the embodiment;

FIG. 8A is a top view for describing the manufacturing method of the wiring board of the embodiment;

FIG. 8B is a sectional view along a VIIIB-VIIIB line in FIG. 8A for describing the manufacturing method of the wiring board of the embodiment;

FIG. 9A is a top view for describing the manufacturing method of the wiring board of the embodiment;

FIG. 9B is a sectional view along a IXB-IXB line in FIG. 9A for describing the manufacturing method of the wiring board of the embodiment;

FIG. 9C is a sectional view along a IXC-IXC line in FIG. 9A for describing the manufacturing method of the wiring board of the embodiment;

FIG. 10A is a top view of an opening of a through hole of a wiring board of a modification 1;

FIG. 10B is a top view of the opening of the through hole of a wiring board of a modification 2;

FIG. 10C is a top view of the opening of the through hole of a wiring board of a modification 3;

FIG. 10D is a perspective view of the opening of the through hole of a wiring board of a modification 4; and

FIG. 10E is a perspective view of the opening of the through hole of a wiring board of a modification 5.

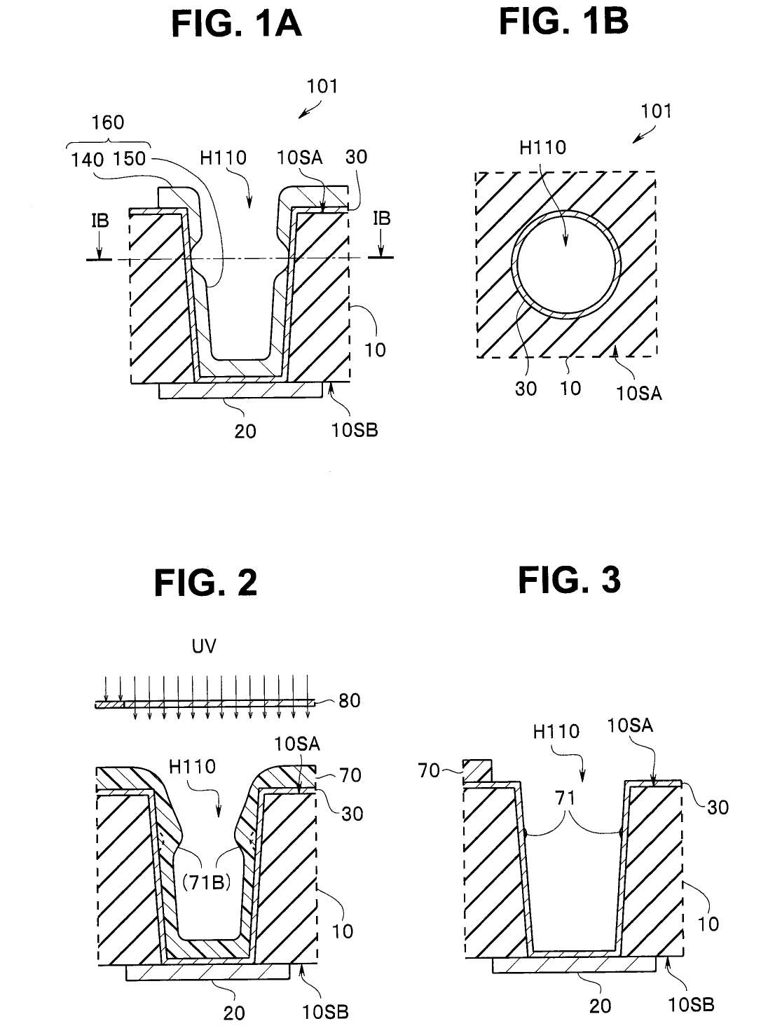

### DETAILED DESCRIPTION OF THE PREFERRED EMBODIMENT

### <Wiring Board of Embodiment>

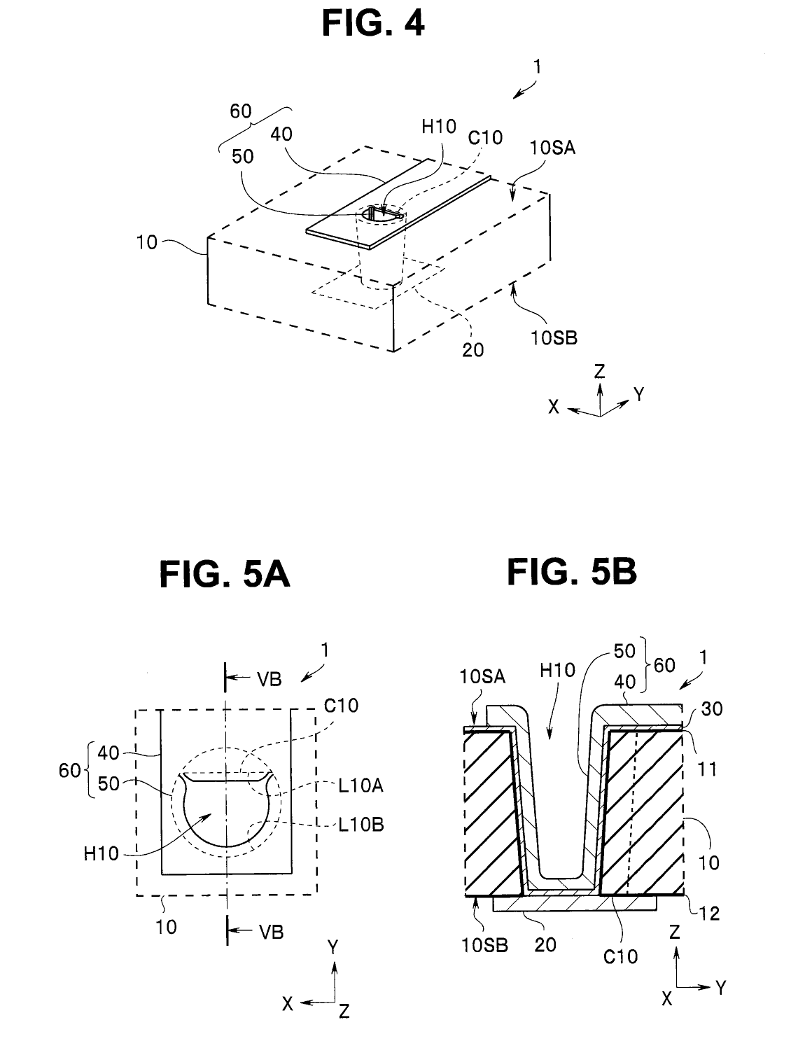

A wiring board 1 of the embodiment will be described as one example of the present invention. The wiring board 1 illustrated in FIG. 4 includes a first main surface 10SA and a second main surface 10SB opposing the first main surface 10SA, and silicon is a base. A through hole H10 with an opening on the first main surface 10SA is a bottomed TSV (through-silicon via), a bottom surface of which is a second conductor 20 disposed on the second main surface 10SB.

A through electrode 50 disposed on an inner surface of the through hole H10 and a first conductor 40 on the first main surface are, as described later, simultaneously formed of an electroplating layer 60 disposed on a conductive layer 30 (see FIG. 5B). The first conductor 40 includes a wiring portion extending in one direction (Y axis direction) from the through electrode 50.

Note that FIG. 4 is a partial view illustrating a vicinity of one through electrode 50, and for example, on a substrate 10, a semiconductor circuit such as an image pickup circuit not illustrated is formed, and many through electrodes 50 or the like are disposed.

On the inner surface of the through hole H10 in a roughly circular shape, a hilling C10 which is a continuous projecting portion from the first main surface 10SA to the second main surface 10SB roughly in parallel with a depth direction (Z axis direction) is provided. That is, as illustrated in FIG. 5A, a shape of the opening, that is, the inner surface of the through hole H10 is a roughly D shape formed of a linear portion L10A configured by the hilling C10 and a circular arc portion L10B.

As illustrated in FIG. 5A, in the through electrode 50, two lines of broken areas, that is, non-plated areas, roughly in parallel with the depth direction (Z axis direction) exist on both sides of the hilling C10. However, as illustrated in FIG. 5B, the non-plated area does not exist continuously in a direction (XY direction) orthogonal to the depth direction so that the first conductor 40 and the second conductor 20 are connected by the through electrode 50.

As illustrated in FIG. 5B, the first conductor 40, the second conductor 20 and the through electrode 50 and the substrate 10 are electrically separated by an insulating layer 11 and an insulating layer 12. For example, on a wall surface of the through hole H10 and the first main surface 10SA, the insulating layer 11 formed of silicon nitride for example is disposed. The insulating layers 11 and 12 may be a silicon oxide film formed by surface oxidation treatment of the substrate 10 formed of silicon. Note that, on the drawings other than FIG. 5B, the insulating layer 11 and the insulating layer 12 are not illustrated.

As described later, in the through hole, the opening of which is not circular but roughly D-shaped, when a photoresist is applied, a resist pool where the photoresist becomes thick exists continuously in the depth direction along both side faces of the hilling C10. Since the photoresist gathers in the resist pool, a resist residue in a ring shape is not generated.

Note that, since a surface shape of the through electrode 50 is same as an inner surface shape of the through hole H10, on a side face of the through electrode 50, the hilling C10, which is a projecting portion (wall), is provided extending along the depth direction.

As described above, the through electrode 50 passes through from the second main surface 10SB of the substrate 10 to the first main surface 10SA, and conducts the first conductor 40 and the second conductor 20 that are wiring patterns provided on the first main surface 10SA and the second main surface 10SB, and the hilling C10 is provided on the side face.

In the wiring board of the present embodiment, since the resist residue in the ring shape is not generated, there is no risk that the through electrode 50 gets broken. In addition, as described later, it is easy to manufacture the through hole H10 with the opening in the roughly D shape.

### <Manufacturing Method of Wiring Board of Embodiment>

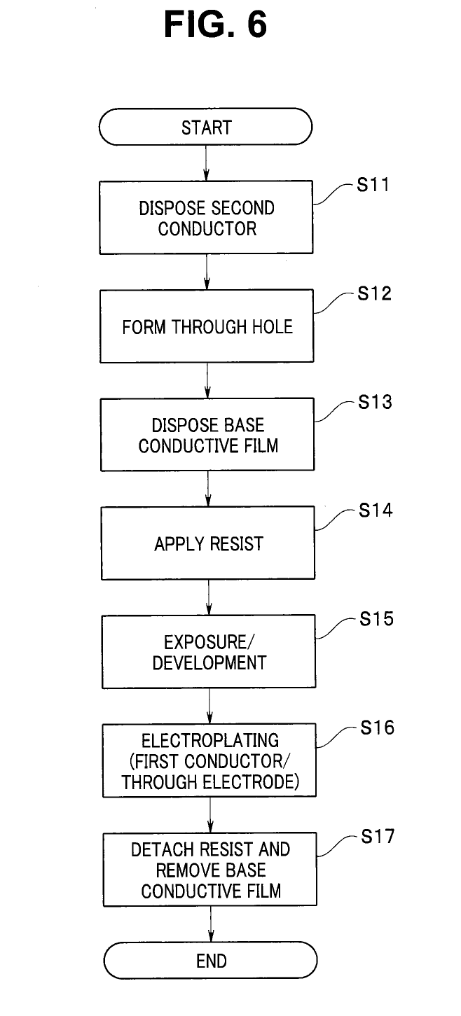

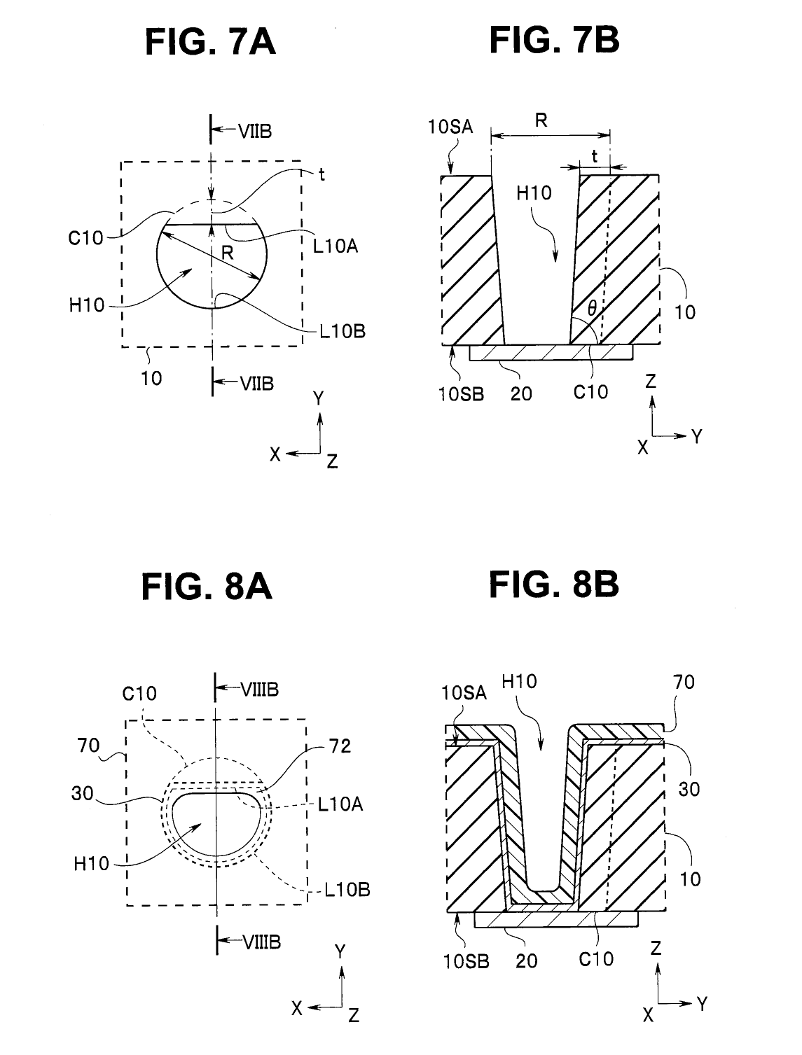

Along a flowchart in FIG. 6, the manufacturing method of the wiring board of the embodiment will be described.

### <Step S11> Second Conductor Disposing Process

On the second main surface 10SB of the substrate 10 including the first main surface 10SA and the second main surface 10SB and formed of silicon, a semiconductor circuit is formed using a semiconductor manufacturing technology. On the second main surface 10SB, an image pickup circuit such as a CCD is formed, and the second conductor 20 connected with the image pickup circuit is disposed further. The second conductor 20 is an aluminum layer with a film thickness of 1 μm, for example.

### <Step S12> Through Hole Forming Process

The through hole H10 passing through the first main surface 10SA and the second main surface 10SB is formed. For example, with a silicon oxide film with a D-shaped opening not illustrated as an etching mask, the silicon of the substrate 10 is removed by Deep-RIE (reactive-ion-etching), the insulating layer 12 is further removed by dry etching or wet etching, and the through hole H10, an opening shape of which is the D shape, is formed.

In etching, since the second conductor 20 is an etching stop layer, the second conductor 20 becomes the bottom surface of the through hole H10. An inclination angle θ of the inner surface of the through hole H10 is 75 degrees to 85 degrees. That is, the shape of the bottom surface of the through hole H10 is the same D shape as the opening shape, but an area of the bottom surface is smaller than the area of the opening.

Note that, to a maximum opening width of the through hole H10, that is, an opening diameter R of the through hole H10 in the roughly circular shape, it is preferable that a height t of the hilling C10 be 3% or more to 30% or less. For example, in a case that the opening diameter R of the through hole H10 is 30 μm, it is preferable that the height t of the hilling C10 be 0.9 μm to 9 μm. When the height t is the range lower limit or higher, two elongated spaces along both side faces of the hilling C10 sufficiently function as the space of the resist pool so that the resist residue in the ring shape is not generated. In addition, when the height t is the range upper limit or lower, it is easy to form the through hole H10 and dispose the conductive layer 30. Note that, when a planar view area of the hilling C10 is 30% or less of the planar view area of the through hole H10, it is easy to dispose the conductive layer 30.

### <Step S13> Conductive Layer Disposing Process

By a CVD method or a sputtering method or the like, the conductive layer 30 for electroplating is disposed on the first main surface 10SA and the inner surface (the wall surface and the bottom surface) of the through hole H10. The conductive layer 30 is formed of a copper layer of 1 μm with a titanium layer of 0.3 μm as a base, for example.

### <Step S14> Resist Applying Process

As illustrated in FIG. 8A and FIG. 8B, the positive photoresist 70 is applied to the inner surface of the through hole H10 and the first main surface 10SA by a spray coater for example. The thickness of the photoresist 70 may be equal to or thicker than the thickness of the electroplating layer 60.

Some of the liquid photoresist 70 applied to a periphery and the inner surface of the through hole H10 is concentrated at a lower part of both side faces of the hilling C10, and forms a resist pool 72.

In a through hole in a simple circular shape, since any part of a circular arc is in a same positional relation with an opening parallel plane, a thickness distribution (overhung area) of the photoresist is generated in the ring shape in parallel with the opening. In contrast, in the through hole H10, the two spaces are formed along both side faces of the hilling C10 in parallel with the depth direction. In the spaces along both side faces of the hilling C10, the linear portion L10A and the circular arc portion L10B intersect. In the space held between two surfaces, the photoresist 70 is gathered by interfacial tension, and the resist pool 72 is formed.

In the through hole H10, the photoresist 70 is gathered in the resist pool 72 so that the resist does not form the overhung area in the ring shape.

The liquid photoresist 70 is heated by a hot plate for example after being applied and is turned to a solid film when a solvent evaporates.

### <Step S15> (Exposure/Development) Process

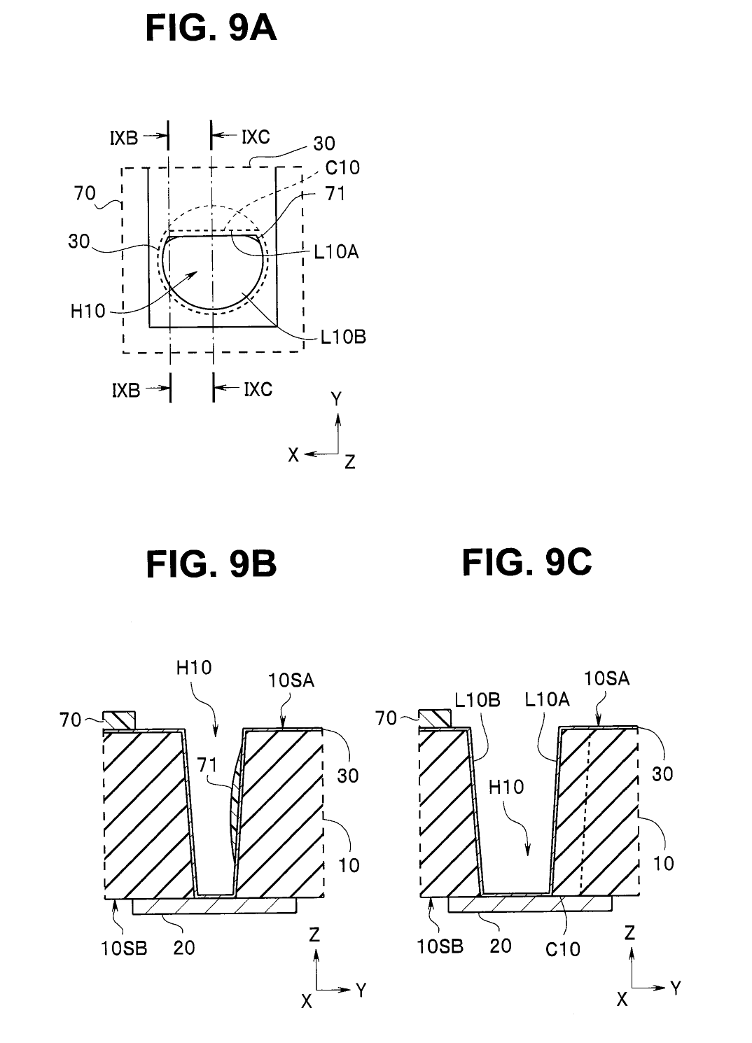

Similarly to FIG. 2, ultraviolet light (UV) is pattern exposed through a photomask 80. Since the photoresist 70 in a UV exposed area becomes soluble to a developer, the photoresist 70 is removed in a development process, and a resist pattern is formed as illustrated in FIG. 9A to FIG. 9C.

As illustrated in FIG. 9B, since the photoresist in the resist pool 72 is thick, some may become a resist residue 71. However, the resist residue 71 is in parallel with the depth direction (Z axis direction). Therefore, as illustrated in FIG. 9C, the resist residue does not exist on the wall surface at a center portion of the linear portion L10A and the center portion of the circular arc portion L10B.

### <Step S16> Electroplating Process

The electroplating layer 60 is formed with the conductive layer 30 as a cathode. For example, the electroplating layer 60 is a copper plating layer with a film thickness of 10 μm formed with a copper plate as an anode using copper sulfate plating liquid. By using the copper sulfate plating liquid containing a predetermined addition agent, the electroplating layer 60 of a uniform thickness is formed on the inner surface of the through hole H10.

The electroplating layer 60 is not formed in the area where the conductive layer 30 is covered with the photoresist 70. Therefore, as illustrated in FIG. 4, the through electrode 50 on the inner surface of the through hole H10 and the patterned first conductor 40 on the first main surface 10SA are simultaneously formed.

Note that the electroplating layer 60 is not formed on the conductive layer 30 covered with the resist residue 71. Therefore, in lower areas of both side faces of the hilling C10, the non-plated areas where the through electrode 50 is not disposed are present respectively. However, the resist residue 71 is in a linear shape along the depth direction of the through hole H10, and is not in the ring shape in parallel with an opening surface. Therefore, the through electrode 50 is not disconnected between the second conductor 20 and the first conductor 40.

### <Step S17> (Resist Detachment/Conductive Layer Removal) Process

A resist pattern 70 and the resist residue 71 are detached by a release agent, an organic solvent for example, and further, the conductive layer 30 not covered with the electroplating layer 60 is removed by an etching method or an ion milling method or the like, and the wiring board 1 illustrated in FIG. 4, FIG. 5A and FIG. 5B is completed.

According to the manufacturing method of the wiring board of the present embodiment, the first conductor 40 and the second conductor 20 can be easily and surely conducted by the through electrode 50.

Note that, depending on a resist applying condition or the like, the resist residue may be generated at the center portion of the circular arc portion L10B away from the two lines of the resist pool 72. However, there is no risk that the resist residue is generated at the linear portion L10A held between the two lines of the resist pool 72. That is, the through electrode 50 can surely conduct the first conductor 40 and the second conductor 20 at least at the linear portion L10A. That is, it is preferable that the through hole H10 include a planar portion on at least a portion of the wall surface.

Therefore, on the substrate 10 where the through hole H10 with the opening in the D shape including one hilling C10 on the inner surface in the circular shape, it is preferable that the opening in an extending direction (Y axis direction) of the wiring portion of the first conductor 40 be the linear portion L10A.

As described above, the wiring board 1 includes the hilling C10 for positively configuring the resist pool in the through hole H10. However, because of process variation, it is not always true that the resist residue exists when the electroplating layer 60 is formed at the lower portion of the side face of the hilling C10 to be the resist pool. In addition, it is not always true that the resist residue exists at both lower portions of both side faces of the hilling C10. Therefore, it is not always true that the non-plated area where the through electrode 50 is not disposed is provided in all of the plurality of through electrodes 50 on the wiring board after being manufactured. However, when the area where the through electrode 50 is not disposed is present at the lower portion of at least one side face of both side faces of the hilling C10 of the through hole of at least one of the plurality of through electrodes 50, it can be considered as the wiring board manufactured by the present invention.

### <Modifications>

Wiring boards 1A-1E of the modifications are similar to the wiring board 1 of the embodiment and have the same effects, the same signs are attached to components having the same functions, and the description of these components is omitted.

That is, in the wiring boards 1A-1E of the modifications, on the inner surface of the through hole in the roughly circular shape, at least one of a groove which is a continuous recessed portion and a hilling which is a continuous projecting portion, from the first main surface 10SA to the second main surface 10SB in parallel along the depth direction (Z axis direction) is provided.

### <Modification 1>

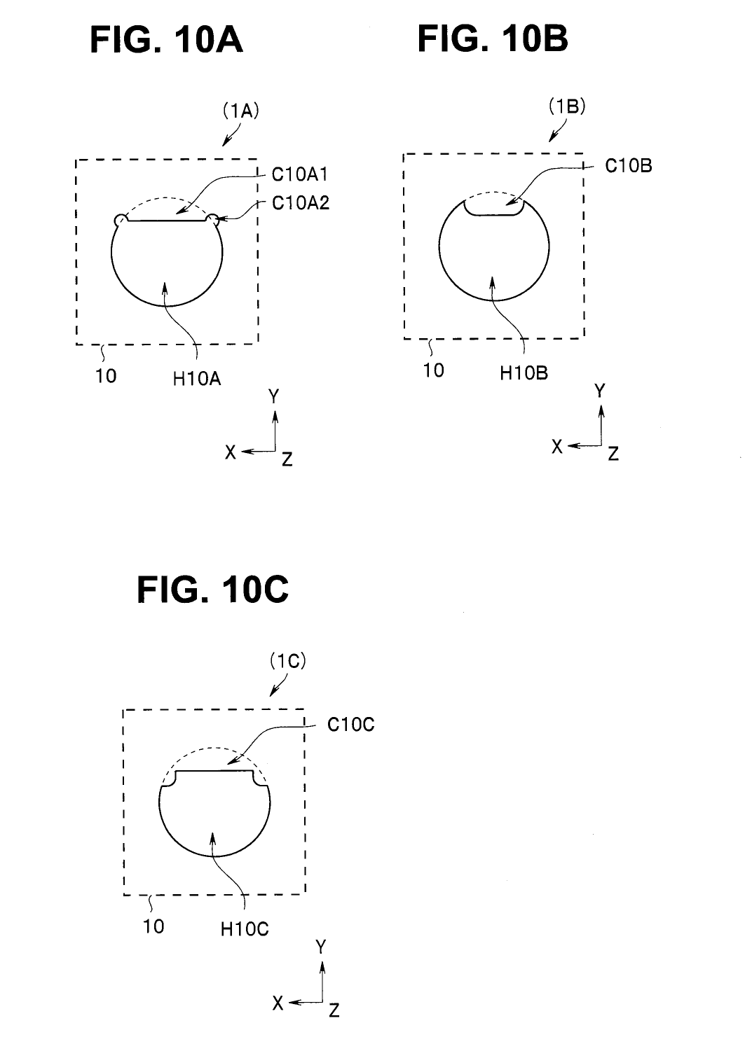

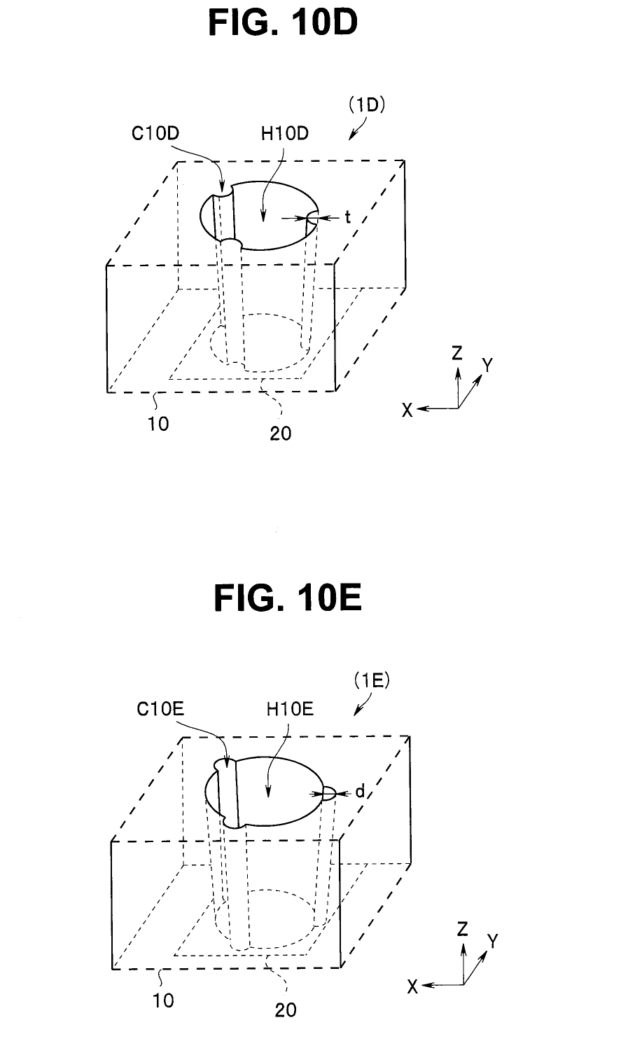

As illustrated in FIG. 10A, a through hole H10A of a wiring board 1A of the present modification includes grooves C10A2 respectively on both end side faces of a hilling C10A1.

That is, on the inner surface of the through hole H10A in the roughly circular shape, one hilling C10A and two grooves C10A2 from the first main surface 10SA to the second main surface 10SB in parallel with the depth direction are provided.

In the through hole H10A, an inside of the groove C10A2 becomes the resist pool.

### <Modification 2>

As illustrated in FIG. 10B, on the inner surface of a through hole H10B of a wiring board 1B of the present modification, one hilling C10B is provided from the first main surface 10SA to the second main surface 10SB in parallel with the depth direction.

At both ends of the hilling C10B, the resist tends to be concentrated more than at the hilling C10.

### <Modification 3>

As illustrated in FIG. 10C, on the inner surface of a through hole H10C of a wiring board 1C of the present modification, a convex hilling C10C is provided from the first main surface 10SA to the second main surface 10SB in parallel with the depth direction.

As in the wiring board 1A to the wiring board 1C, the through hole may be in the roughly D shape. That is, it is preferable that the through hole include a planar portion on at least a portion of the wall surface.

### <Modification 4>

As illustrated in FIG. 10D, on the inner surface of a through hole H10D of a wiring board 1D of the present modification, three hillings C10D of the height t from the first main surface 10SA to the second main surface 10SB in parallel with the depth direction are provided.

### <Modification 5>

As illustrated in FIG. 10E, on the inner surface of a through hole H10E of a wiring board 1E of the present modification, three grooves C10E of a depth d from the first main surface 10SA to the second main surface 10SB in parallel with the depth direction are provided.

Like the wiring board 1D and the wiring board 1E, the through hole may include a plurality of grooves or a plurality of hillings at separated positions. In the through hole with the plurality of grooves or the plurality of hillings, the resist residue is not easily generated at the center portion between the grooves or the hillings. Note that it is preferable that the plurality of grooves or the plurality of hillings be in a rotationally symmetric positional relation to a center axis of the through electrode.

As described above, for the wiring board, the opening shape (sectional shape) of the through hole is the roughly circular shape but at least either one of the groove and the hilling for configuring a resin pool may be provided. For example, the through hole H10 may be in a shape that the projecting portion by the hilling and the recessed portion by the groove be provided on a portion of a rectangular opening.

Note that, also in the modifications above, it is preferable that the groove or the hilling not be present on the inner surface in the extending direction (Y axis value increasing direction) of the wiring portion. In addition, it is preferable that a depth d of the groove or the height t of the hilling be 3% or more to 30% or less of the maximum opening width (inner diameter R) of the through hole in the roughly circular shape.

The present invention is not limited only to the embodiments explained above and can be variously modified and carried out in a range not departing from the spirit of the invention.

What is claimed is:

1. A wiring board with silicon as a base, including a first main surface and a second main surface opposing the first main surface, in which a first conductor on the first main surface and a second conductor on the second main surface are connected by a through electrode formed of an electroplating layer extending from the first conductor and disposed on an inner surface of a through hole, a bottom surface of which is the second conductor,
wherein, on the inner surface of the through hole, at least either one of a groove which is a continuous recessed portion and a hilling which is a continuous projecting portion, is provided from the first main surface to the second main surface in parallel with a depth direction.

2. The wiring board according to claim 1, wherein a depth of the groove or a height of the hilling is 3% or more to 30% or less of an opening width of the through hole.

3. The wiring board according to claim 2, wherein at least either a plurality of grooves or a plurality of hillings are provided on the inner surface of the through hole.

4. The wiring board according to claim 3,
wherein the first conductor includes a wiring portion extending from the through electrode, and
the groove or the hilling is not provided on the inner surface in an extending direction of the wiring portion.

5. The wiring board according to claim 2, wherein an opening of the through hole with the hilling is in a roughly D shape including a circular arc portion and a linear portion configured by the hilling.

6. The wiring board according to claim 5,
wherein the first conductor includes a wiring portion extending from the through electrode, and
the opening in an extending direction of the wiring portion is the linear portion.

7. The wiring board according to claim 1, comprising
a plurality of through electrodes,
wherein at least one of the plurality of through electrodes has an area where the through electrode is not disposed inside the groove or at a lower portion of the hilling.

8. A manufacturing method of a wiring board with silicon as a base, including a first main surface and a second main surface, in which a first conductor on the first main surface and a second conductor on the second main surface are connected by a through electrode disposed on an inner surface of a through hole, a bottom surface of which is the second conductor, the manufacturing method comprising:
a process of forming the through hole from the first main surface to the second conductor of the second main surface;
a process of disposing a conductive layer covering the first main surface and an inner surface and a bottom surface of the through hole;
a process of coating a positive photoresist on the first main surface and the inner surface and the bottom surface of the through hole;
a process of detaching the photoresist covering an area to dispose the first conductor of the first main surface and the inner surface and the bottom surface of the through hole by pattern exposure of ultraviolet light through a photomask and development;
a process of disposing an electroplating layer with the conductive layer as an electrode; and
a process of detaching the photoresist, and further removing the conductive layer not covered with the electroplating layer,
wherein, on the inner surface of the through hole formed in the process of forming the through hole, at least either one of a groove and a hilling is provided from the first main surface to the second main surface in parallel with a depth direction.
